(19) United States
(12) Patent Application Publication
(10) Pub. No.: US 2016/0170831 A1
(43) Pub. Date: Jun. 16, 2016

(54) Response Control for Memory Modules That Include or Interface With Non-Compliant Memory Technologies

(71) Applicant: Hewlett-Packard Development Company, L.P., Houston, TX (US)

(72) Inventors: Gregg B. Lesartre, Fort Collins, CO (US); Andrew R. Wheeler, Fort Collins, CO (US); John E. Tillema, Fort Collins, CO (US); Alan Jerome Wade, Fort Collins, CO (US)

(21) Appl. No.: 14/907,363

(22) PCT Filed: Jul. 25, 2013
(86) PCT No.: PCT/US2013/052031

§ 371 Date: Jan. 25, 2016

(51) Int. Cl. G06F 11/10; G06F 3/06; G11C 29/52

(52) U.S. Cl. CPC G06F 11/1068; G11C 29/52; G06F 3/0619; G06F 3/064; G06F 3/0679

(57) ABSTRACT

Example embodiments relate to response control for memory modules that include or interface with non-compliant memory technologies. A memory module may include an interface to a memory bus that complies with a data transfer standard, wherein the memory bus communicates with a memory controller, and an interface to a non-compliant memory technology that does not comply with the data transfer standard. The memory module may include a command monitoring circuit to determine whether a command from the memory controller has been or will be completed by the non-compliant memory circuit within a defined amount of time within which a command should be completed according to the data transfer standard. The memory module may include an error causing circuit that signals to the memory controller or an operating system when the command has not or will not complete within the defined amount of time.

### BACKGROUND

Dynamic random-access memory (DRAM) is a type of volatile memory that stores bits of data in capacitors that require power in order to hold the values of the bits. Because power is required to hold the values, DRAM is referred to as a volatile or dynamic memory, as opposed to static memory. Various modern computing systems utilize DRAM DIMMs to implement system memory. A DIMM (dual in-line memory module) is a computer memory component or module that includes a number of DRAM memory circuits. A DIMM may be a printed circuit board and may include DRAM memory circuits mounted thereon. A DIMM may plug into or connect with a motherboard of a computing system to interface with a memory bus, which may in turn interface with a memory controller.

### BRIEF DESCRIPTION OF THE DRAWINGS

The following detailed description references the drawings, wherein:

FIG. 1 is a block diagram of an example computing system that implements response control for memory modules that include or interface with non-compliant memory technologies;

FIG. 2 is a block diagram of an example responder module used to implement response control for memory modules that include or interface with non-compliant memory technologies;

FIG. 3 is a block diagram of example computing system that implements response control for memory modules that include or interface with non-compliant memory technologies;

FIG. 4 depicts a flowchart of an example method for response control for memory modules that include or interface with non-compliant memory technologies;

FIG. 5 depicts a flowchart of an example method for response control for memory modules that include or interface with non-compliant memory technologies;

FIG. 6 is a block diagram of an example computing system for response control for memory modules that include or interface with non-compliant memory technologies; and

FIG. 7 is a flowchart of an example method for response control for memory modules that include or interface with non-compliant memory technologies.

### DETAILED DESCRIPTION

Various DIMMs may comply with the double data rate (DDR) data transfer standard. In such a scenario, in order for the memory controller and the memory bus to communicate with a DDR-compliant DIMM, the memory controller and memory bus may be required to be DDR-compliant as well. Thus in various computing systems, the memory controller and the memory bus are designed to operate according to the DDR data rate transfer standard (i.e., they are DDR compliant). In computing systems that include a DDR compliant memory controller, various other components of the computing system (e.g., central processor, motherboard, etc.) may be designed to interface with the DDR compliant memory controller. Furthermore, DDR compliant memory controllers, because they are designed to interface with a DDR compliant memory bus and DDR compliant DIMMs, may be designed to expect certain memory communication characteristics. For example, when the memory controller issues a read command (simply referred to as a “read”) to a DIMM, the memory controller may expect the DIMM to provide the requested read data within a defined (e.g., short) period of time. In other words, the DDR specification may require that a DIMM have a consistent read latency, e.g., that it provide requested read data after a predictable, defined and relatively fast period of time. The DDR standard may be referred to as a deterministic protocol, meaning that when commands are sent from the memory controller to the memory bus, it is expected that the commands will complete in a certain number of cycles. DDR DRAM memory circuits are able to complete reads issued to them within such a predictable, defined and relatively fast period of time, but other types of memory circuits/technologies may not.

In some scenarios, it may be desirable to implement non-volatile memory technologies (e.g., FLASH, PC-RAM, STT-MRAM, ReRAM, etc.) that interface with a DDR compliant memory bus and memory controller (e.g., via a DIMM or similar memory module). Various non-volatile memory technologies may be unable to ensure that reads issued to them will be completed (e.g., requested read data ready) within a predictable, defined and/or relatively fast period of time. For example, non-volatile memory technologies, instead of returning read data after a consistent latency, may indicate (e.g., via a wire, line or signal) when read data is ready. Because these various non-volatile memory technologies may not behave as may be expected by a DDR-compliant memory controller, such a memory controller may be unable to communicate with such memory technologies.

Some approaches to handing non-volatile memory technologies may include adding an extra wire or line such that a DIMM may signal when the DIMM (e.g., a non-volatile memory technology on or connected to the DIMM) has read data that is ready to be sent to the memory controller. Such an approach may require modification to several components of the computing system, however. For example, the motherboard, memory bus, and memory controller may need to be modified to run an extra line/wire for such a signal. Furthermore, the memory controller may need to be modified to understand how to handle/support the extra line/wire and signal. In other words, a non-compliant (e.g., non-DDR compliant) motherboard, memory bus and memory controller, at least, may be required for such an approach.

Other approaches to handing non-volatile memory technologies may require that the memory controller know the latencies of the memory technologies that it issues commands to. For such approaches, the memory controller may issue test commands to the memory technologies to determine their longest latencies. Then the memory controller may store the latencies of the various memory technologies it communicates with and may use such latencies going forward when issuing commands. Yet other approaches to handling non-volatile memory technologies may include connecting these technologies elsewhere in the computing system (e.g., not on or via a memory module such as a DIMM). In such a scenario, in order for the memory controller (and perhaps a processor) to read data from these non-volatile memory technologies, the data may first be required to be explicitly moved to the DIMM (e.g., DRAM memory circuits on the DIMM) before the memory controller and/or processor can access the data. Such a preliminary explicit transfer of data may be time consuming, among other potential problems.

The present disclosure describes response control for memory modules that include or interface with non-compliant memory circuits/technologies. The present disclosure describes a response control module (e.g., on a memory module such as a DIMM) that allows non-compliant (e.g., non-volatile) memory circuits/technologies to interface with a compliant (e.g., DDR compliant) memory bus and a compliant (e.g., DDR compliant) memory controller. This may allow the non-compliant memory circuit/technologies to take advantage of benefits (e.g., performance benefits) of communicating more directly with the memory controller. The present disclosure describes a response control module between the memory controller (e.g., a modified but still compliant memory controller) and at least one non-compliant memory circuit/technology. The response control module may analyze commands (e.g., reads and writes) received by the memory controller directed to at least one non-compliant memory technology and may know when such commands are expected to be completed according to a particular data transfer protocol (e.g., DDR). If the command is not completed (e.g., in the case of a read) or will not be completed (e.g., in the case of a write) by the memory technology as expected, the response control module may signal an error to the memory controller (or an operating system), and the memory controller (or operating system) may handle the error such that the memory controller still communicates with the memory module in a compliant manner (e.g., according to a DDR protocol). For example, in the case of a read command, the response control module may signal (e.g., to the memory controller or the operating system) when the return data is not available as may be expected according to the DDR protocol. Based on this signal, the memory controller, operating system or some other module of a computing system may retry the read command at a later time. The response control module may use a parity bit or ECC (error correcting code) bits of the compliant interface to signal when a command may not be completed as expected. Such a signaling mechanism may allow a compliant memory controller to interact with memory circuits/technologies of varied and unknown latencies.

The present disclosure may also offer benefits over some approaches that include adding an extra wire or line such that a DIMM may signal when the DIMM (e.g., a buffer mechanism with limited space) is not ready to accept another write. The present disclosure describes a solution where an error or retry signal may be sent via compliant (e.g., DDR compliant) interfaces and wiring paths. For example, the response control module may use a parity bit or ECC (error correcting code) bits of the compliant interface to signal when a command may not be completed as expected. Such parity or ECC bits may already exist in an interface between the memory module (e.g., DIMM) and the memory bus and memory controller. The present disclosure may allow high capacity, lower-cost, non-volatile memories to interface with the memory controller, which may allow such memories to operate alongside conventional memories (e.g., DDR DRAM memories) in a computing system.

Throughout this disclosure, the term “compliant” (e.g., as in compliant memory technology or compliant memory controller) may refer to a computer component that is designed to comply with a particular data transfer standard (e.g., DDR or other data transfer standard). Likewise, the term “non-compliant” may refer to a computer component that is not designed to comply with (or is incompatible with) the particular data transfer standard. The term “data transfer standard” may refer to a protocol by which data is transferred over a number of communication wires or lines (e.g., metal wires over which information is sent and/or received). The data transfer standard may specify a number of data transfer cycles, timing of various commands (e.g., reads, writes, etc.), and various other details that may be required for one computer component to send and/or receive data from another computer component. As one specific example, if the data transfer standard is DDR, then a computer component may be a compliant (e.g., DDR compliant) computer component or a non-compliant computer component (e.g., non-DDR compliant) with respect to the DDR data transfer standard. In the case of DDR, some non-volatile memory circuits or technologies are examples of non-compliant computer components, for example, because they do not operate like volatile DDR memory circuits. Thus, in various descriptions below, when reference is made to a non-volatile memory circuit or technology, it may be inferred it is a non-compliant computer component. Examples of non-volatile memory technologies (e.g., that are non-DDR compliant) may include PCRAM, SATA, STT-RAM, reRAM, memristor, FLASH and spinning disk on PCIe. The present disclosure may apply to various other types of non-volatile memory technologies as well. Throughout this disclosure, the term “command” (e.g., as in a write command or read command) may refer to a multi-bit digital value, where each bit may be sent over a dedicated communication wire or line. A command may have multiple “fields” where each field is a multi-bit digital value. Example fields may be “address” (addr), “command” (cmd), “data,” “parity” and “ECC.” The command field (i.e., cmd) should not be confused with the broader command (e.g., write or read command). The cmd field may indicate what type of command is intended by the broader command, and the broader command may include additional information required to execute the command (e.g., addr and data).

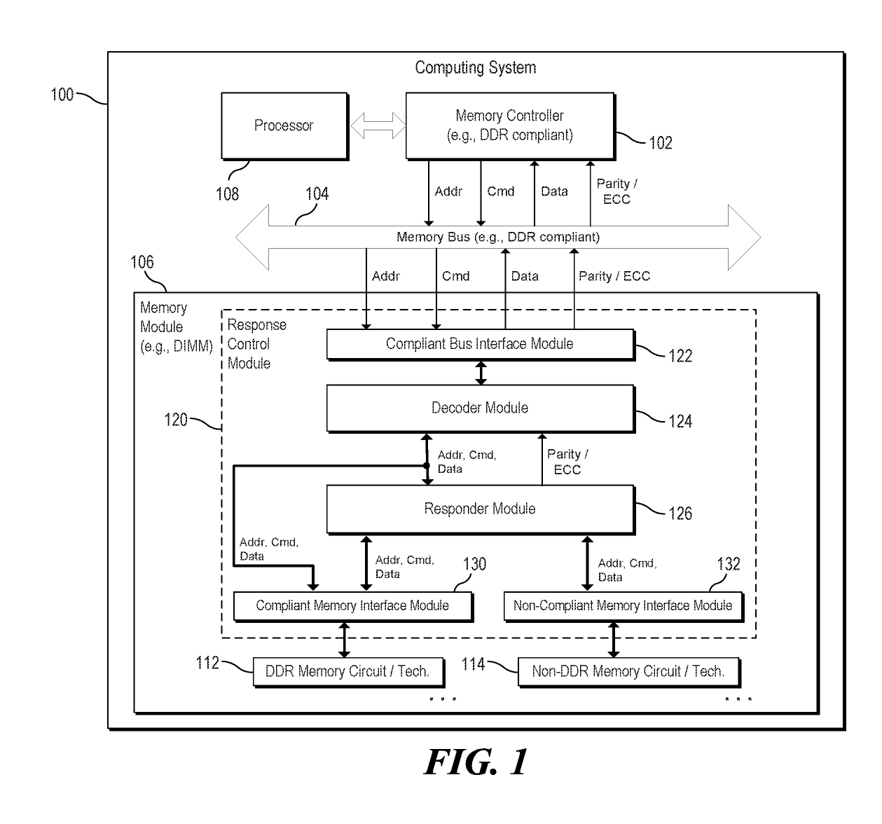

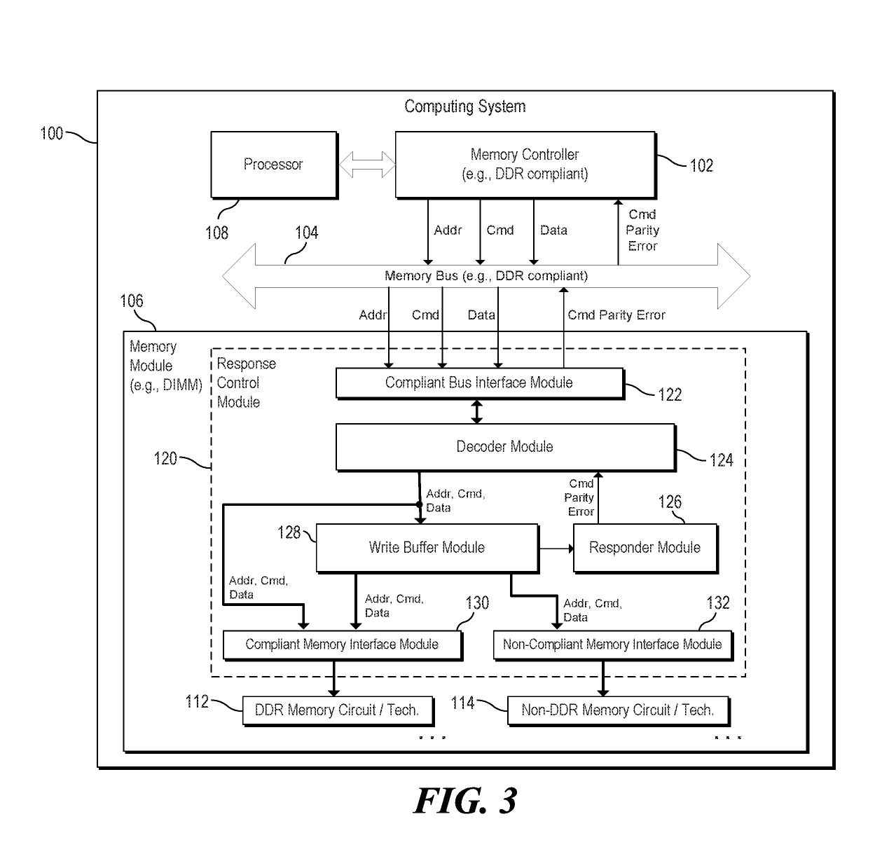

FIG. 1 is a block diagram of an example computing system 100 that implements response control for memory modules that include or interface with non-compliant memory technologies. Computing system 100 may be any computing system or computing device that includes a memory controller (e.g., 102) that accesses a memory module (e.g., 106), e.g., via a memory bus (e.g., 104). In the example of FIG. 1, the data transfer standard referred to is DDR; however, it should be understood that the techniques and solutions described herein may be used with any other data transfer standard. Computing system 100 may include a memory controller 102, a memory bus 104, a memory module 106 and a processor 108. As described in more detail below, memory module 106 may be modified when compared to memory modules (e.g., DIMMs) that include only compliant memory circuits/technologies (e.g., DDR memory circuits/technologies). Computing system 100 may also include (although not shown in FIGS. 1 and 3) a number of memory modules that include only compliant memory circuits/technologies, and such memory modules may be in communication with memory bus 104.

Memory controller 102 may send memory commands (e.g., read commands, write commands, etc.) to memory bus 104, which may in turn cause the memory commands to arrive at memory module 106. In some scenarios, return data may be sent from memory module 106 to memory bus 104, and in turn may arrive back at memory controller 102. In order to interface with memory bus 104, memory controller 102 may connect to memory bus 104 using, for example, a number of address (i.e., addr) wires/lines, a number of command (i.e., cmd) wires/lines and a number of data wires/lines, as shown in FIG. 1. The interfaces between memory controller 102, memory bus 104 and memory module 106 may also include a number of parity or ECC wires/lines, as shown by “Parity/ECC” in FIG. 1. Memory controller 102 may send memory commands to memory module 106 and receive data from memory module 106 on behalf of some other component of computing system 100, for example, processor 108. It should be understood that, although FIG. 1 shows processor 108 interfacing with memory controller 102, it may be the case that at least one component is located between processor 108 and memory controller 102. It may also be the case that some other component (e.g., other than a processor) interfaces with memory controller 102 to communicate with memory module 106.

Memory controller 102 may be a compliant (e.g., DDR compliant) memory controller, which means that memory controller 102 may be capable of operating according to a particular data transfer standard (e.g., DDR). Thus, memory controller 102 may send data to and receive data from memory bus 104 as specified by the data transfer standard, which may specify details such as an amount of time (e.g., a predictable, defined and relatively fast period of time) within which read commands may be completed by memory module 106. Memory bus 104 may also be compliant (e.g., DDR compliant), which means memory bus 104 may receive and transmit commands as specified by the data transfer standard. In the specific case of the a DDR data transfer standard, memory controller 102 may send read commands to memory bus 104 at a predictable rate and memory bus 104 may consistently send the read commands to memory module 106 at a predictable rate. Memory controller 102 may expect to receive return data in response to these read commands after a predictable defined amount of time. If such return data is unable to be returned as expected, memory controller 102 may have to retry the read command, for example, because the DDR standard may not support waiting longer for read return data.

Memory module 106 may be any type of memory module (e.g., DIMM) that includes or interfaces with memory circuits and/or memory technologies (e.g., DRAM circuits). Memory module 106 may be, for example, a printed circuit board that plugs into or connect to a motherboard of the computing system 100. Memory module 106 may receive commands (e.g., read commands) from memory bus 104. In order to interface with memory bus 104, memory module 106 may connect to memory bus 104 using, for example, a number of address (i.e., addr) wires/lines, a number of command (i.e., cmd) wires/lines, a number of data wires/lines and a number of parity or ECC wires/lines as shown in FIG. 1. Memory module 106 may be capable of receiving commands from memory bus 104 in a compliant manner (e.g., at a rate specified by the data transfer standard). Memory module 106 may complete such received commands in a period of time defined by the data transfer standard, or it may start to work on the commands and may, in the meantime, signal to the memory controller (or operating system) that the command was unable to be completed in time, which may trigger a retry of the command. In some examples, where response control module 120 is a separate computer component (e.g., as described in more detail below) from memory module 106, response control module 120 may have addr, cmd, data, parity/ECC wires/lines that interface with memory bus 104, and memory module 106 may have connections to interface with the response control module 120.

Memory module 106 may include or may interface with at least one compliant memory circuit or technology (e.g., DDR memory circuit/technology 112). Memory module 106 may include or may interface with at least one non-compliant memory circuit or technology (e.g., non-DDR memory circuit/technology 114). In some examples, memory module 106 may include or interface with both at least one compliant memory circuit/technology (e.g., 112) and at least one non-compliant memory circuit/technology (e.g., 114). In some examples, memory module 106 may only include or interface with at least one non-compliant memory circuit/technology (e.g., 114). In such examples, memory module 106 may not include or interface with a compliant memory circuit/technology (e.g., 112), and related components and/or modules (e.g., module 130) may be excluded.

Memory module 106 may include a response control module 120. Response control module 120 may, in some situations, be referred to as a response control circuit. As can be seen in FIG. 1, response control module 120 is located between a compliant memory controller 102 and a non-compliant memory circuit/technology (e.g., 114). Response control module 120 may allow non-compliant (e.g., non-volatile) memory technologies (e.g., 114) to interface with a compliant (e.g., DDR compliant) memory bus (e.g., 104) and a compliant memory controller (e.g., 102). Response control module 120 may be implemented as electronic circuitry (i.e., a circuit). In some examples, module 120 may be implemented as hardware only (e.g., static circuitry). In other examples, module 120 may be implemented as a circuitry that is capable of being programmed or configured (e.g., firmware) or as circuitry that is capable of reading and executing instructions (e.g., circuitry with a microprocessor to execute instructions and/or software on a machine-readable storage medium). In one specific example, response control module 120 may be an application-specific integrated circuit (ASIC) and may be attached to or mounted on memory module 106. In other examples, module 120 may be a separate computer component from memory module 106. For instance, module 120 may plug into or connect to a motherboard of computing device 100 to interface with memory bus 104, and then memory module 106 may plug into or connect to module 120.

Response control module 120 may include a number of modules, for example, modules 122, 124, 126, 130 and 132. Each of these modules may be, as mentioned above, electronic circuitry (e.g., hardware and/or firmware) and/or each of these modules may be instructions on a machine-readable storage medium that are executable by a microprocessor of the response control module 120. With respect to the modules described and shown herein, it should be understood that part or all of the executable instructions and/or electronic circuitry included within one module may, in alternate embodiments, be included in a different module shown in the figures or in a different module not shown. Each of the modules shown may or may not be present in various examples, and in some examples, additional modules may be present.

Compliant bus interface module 122 may communicate with memory bus 104 (e.g., via memory module 106) according to a particular data transfer standard (e.g., DDR). For example, compliant bus interface module 122 may be capable of receiving read commands from memory bus 104 at a predictable, defined and relatively fast rate. Compliant bus interface module 122 may also return data (e.g., referred to as “return data”) to memory controller 102 in response to a read command, if the data is ready, within a predictable, defined and relatively fast period of time. Read commands may be intended to read data from at least one compliant memory circuit/technology (e.g., 112) and/or from at least one non-compliant memory circuit/technology (e.g., 114). Compliant bus interface module 122 may also receive write commands and other types of commands, according to the particular data transfer standard. Compliant bus interface module 122 may have a number of connections to interface with memory bus 104, for example, a number of addr, cmd, data and parity/ECC wires/lines, as shown in FIG. 1. Compliant bus interface module 122 may feed commands (e.g., read and/or write commands) to decoder module 124. Compliant bus interface module 122 may also receive return data from decoder module 124 or other modules of response control module 120.

Decoder module 124 may receive commands from compliant bus interface module 122. Decoder module 124 may route commands and/or various fields from commands to various modules of response control module 120. For example, decoder module 124 may determine where to route particular commands (or fields) based on an address (i.e., addr) field of the command. In this respect, various modules of response control module 120 may each be associated with a particular “address space.” As one specific example, various addresses may be associated with non-compliant memory circuits/technologies (e.g., 114) and decoder module 124 may route commands directed to these addresses to non-compliant memory interface module 132, which may in turn route the commands to non-DDR memory circuits/technologies (e.g., 114) that are on (or interface to) memory module 106. Similarly, various addresses may be associated with compliant memory circuits/technologies (e.g., 112). Thus, when decoder module 124 receives a command from compliant bus interface module 122, module 124 may analyze the command (e.g., the addr field) and may route the command appropriately.

Decoder module 124 may, in some instances, route less than the full command (e.g., less than all the fields of the command) to various modules. For example, if decoder module receives read commands to read memory circuits/technologies or registers, module 124 may only route the addr and cmd fields to the memory circuits/technologies or registers. Decoder module 124 may, in some instances, pass through certain bits, wires, lines or fields of a command without modification. For example, if decoder module receives write commands, data lines coming into decoder module 124 (e.g., from module 122) may pass through to a write buffer, for example, because the data wires/lines may not be required to decode an incoming command. Decoder module 124 may receive return data from various modules of response control module 120, for example, module 126. Decoder module 124 may also receive return data from at least one memory circuit/technology (e.g., 112 and/or 114), e.g., via interface modules 130, 132. FIG. 1 may focus mainly on the functional aspects of issuing reads to (and returning data from) the memory circuits/technologies (e.g., 112, 114). FIG. 3 may focus on other functional aspects, for example, issuing writes.

Interface modules 130 and 132 may receive commands (e.g., read commands and/or write commands) or particular fields of commands and may transmit them to their respective memory circuits/technologies (e.g., 112, 114). Interface modules 130 and 132 may also receive return data from their respective memory circuits/technologies and may transmit such data to at least one module of response control module 120, for example, responder module 126. Each of the memory circuits/technologies (e.g., 112, 114) may either be mounted on memory module 106 or may be external to memory module 106. If a memory circuit/technology is external to memory module 106, the respective memory interface module (e.g., 130, 132) may connect to the external memory circuit/technology via a port, connector, set of wires or the like.

Responder module 126 may receive or access commands from decoder module 124, for example, that are directed to a non-compliant memory circuit or technology (e.g., 114). Responder module 124 may determine an amount of time within which commands (e.g., of the particular type being received or accessed) should complete according to a data transfer standard (e.g., DDR). Responder module 124 may analyze the received or accessible commands from module 124 and may determine whether each command is completed (e.g., in the case of reads) or likely will be completed (e.g., in the case of writes) by the non-compliant memory circuit within the amount of time. If a command is completed or likely will be completed by the non-compliant memory circuit within the amount of time, responder module 124 may allow a command response to complete (e.g., in the case of a read) or may do nothing (e.g., in the case of a write). More specifically, in the case of a read, module 124 may allow return data to be returned to memory controller 102. If a command is not completed or likely will not be completed by the non-compliant memory circuit within the amount of time, responder module 124 may signal such a scenario (e.g., an error) to the memory controller 102. Responder module 124 may use a parity bit or error correcting code (ECC) bits to perform the signaling. Based on such a signal, the memory controller or an operating system of computing system 100 may retry the command, e.g., after a period of time.

A parity bit may refer to a bit added to the end of a binary code (i.e., data) that indicates whether the number of 1-value bits in the binary code is even (e.g., an even parity scheme) or odd (e.g., an odd parity scheme). A parity bit may be used to detect whether received data is different than the data that was transmitted, which may indicate an error in transmission, storage, etc. If an error is detected using the parity bit, the data must be discarded and perhaps re-transmitted because a parity bit may not allow for correction of the data. An error correcting code (ECC) may refer to a plurality of bits added to the end of a binary code (i.e., data) that may be used to detect and perhaps correct an error in the data. An ECC may add redundant information to the data. The redundant information may be determined as a function of multiple original bits of the data, and the redundant information may be used to (e.g., via another function) to restore or correct the original data. Various descriptions and/or drawings herein may refer to a parity bit and/or an ECC or ECC bits. It should be understood that various descriptions and/or drawings that refer to a parity bit may apply equally to ECC and vice versa. Thus, a particular example that refers to a parity bit versus ECC bits and vice versa should not be construed as being limiting.

Responder module 126 may use parity or ECC bits to signal when a command is not completed (e.g., in the case of a read) or likely will not be completed (e.g., in the case of a write) by the non-compliant memory circuit within an amount of time expected according to a data transfer protocol. Parity or ECC bits may already be part of the interface between memory module 106 and memory bus 104, and between memory bus 104 and memory controller 102. Thus, no additional bits/wires/lines are required to perform the signaling. In one example, if a single parity bit is used, responder module 126 may set the parity bit to intentionally cause a parity error. Memory controller 102 or an operating system may then recognize and respond to the parity error, as described in more detail below. In this situation, the parity bit may only indicate a single type of error, and thus the memory controller's or operating system's response (e.g., default response or altered response) to the error may need to be a response that is useful (e.g., a command retry) to the responder module 126. Additionally, the response may need to be appropriate for a regular parity error that may occur as a result of an error in data transmission or the like.

As another example, responder module 126 may use multiple ECC bits to signal that a command was not completed in time or likely will not be completed in time. With multiple ECC bits, multiple values, messages or codes may be able to be encoded in the ECC bits. Thus, first of all, responder module 126 may encode the ECC bits such that memory controller 102 or the operating system may distinguish between a real data transmission error, for example, and an error initiated by the response module 126 due to a command not completing on time. Then, responder module 126 may further encode the ECC bits with various “error codes.” Error codes may indicate various additional details about the error initiated by module 126, for example, details such as how long to wait until the command is retried, how many times to retry the command, and the like. In yet another example, various other bits/lines/wires of the interface (e.g., compliant interface) between memory module 106 and memory bus 104 and memory controller 102 may be used to provide details about an error. For example, the “data” field of the interface may be encoded (e.g., by module 126) with details about the error. Thus, in the case of an error initiated by module 126, all the available bits/lines/wires of the interface may be used to include additional details about the error. After all, the command may be retried anyway, so the other available bits (e.g., data response bits) may otherwise go unused.

Memory controller 102 may need to be designed and/or configured to interpret and/or act upon signals (e.g., error signals) from memory module 106 that indicate that a command was not or likely will not be completed as expected according to the data transfer protocol. However, it should be understood that an interface of the memory controller 102 may still comply with a particular data transfer standard (e.g., DDR). For example, whenever memory controller 102 sends commands, it may send the commands according to a particular data transfer standard (e.g., DDR). Likewise, whenever memory controller 102 receives return data, it may receive it according to a particular data transfer standard (e.g., DDR). Memory controller 102 may, for example, retry a previously sent command based on a signal from memory module 106, but both the original command and the retried command may be sent according to the particular data transfer standard. Thus, even though memory controller 102 may need to be altered when compared to a memory controller that does not implement command retries, an altered memory controller may still be able to interface with all other computer components of computing system 100 that comply with the data transfer standard. For example, a motherboard, including a socket for a DIMM memory module may not need to be altered (e.g., they may remain compliant). As one specific scenario, in some systems, the memory controller is part of a central processor (e.g., 108), and thus, an existing processor may simply be swapped out with a processor that includes an altered memory controller 102, and then the computing system may be ready to implement command retries.

Memory controller 102 may, by default, be designed and/or configured to act upon a parity or ECC error. For example, memory controller 102 may automatically retry the command in the case of a parity error, or it may automatically attempt to correct the data in the case that ECC bits are provided. If the default response of memory controller 102 is not useful to responder module 126 (e.g., causing command retries), then memory controller 102 may be altered/modified. Memory controller 102 may be designed and/or configured to recognize an error initiated by responder module 126 (e.g., as opposed to a real data transmission error). Memory controller 102 and responder module 126 may need to use a common encoding scheme (e.g., using the multiple ECC bits and/or other available bits such as data bits) such that encoding collisions are avoided. For example, if a real data transmission error occurred and the memory controller 102 acted upon the error as though it were an error initiated by responder module 126, this may cause problems. In some situations, memory controller 102 may detect and decode an error code, e.g., from multiple ECC bits.

Memory controller 102 may automatically retry the command based on the error. Memory controller 102 may wait an amount of time after receiving the error before retrying the command. The amount of time before retry may change, may be configurable, and may, for example, be indicated in an error code sent from responder module 126. Memory controller 102 may only retry the command a number of times before it “gives up” or stops attempting to retry the command. The number of retries may change, may be configurable, and may, for example, be indicated in an error code sent from responder module 126.

In some situations, computing system 100 includes a main operating system (OS), for example, running on processor 108. The OS may be designed and/or configured to interpret and/or act upon signals from memory module 106 that indicate that a command will not be completed as expected according to the data transfer protocol. In some examples, the OS may handle parity and/or ECC errors (e.g., “real” parity/ECC errors and errors initiated by responder module 126) instead of the memory controller 102. For example, parity and/or ECC errors may propagate through the memory controller 102 back to the OS (e.g., the trap handler in the OS), and the OS may then take appropriate action. In other examples, the OS and the memory controller may operate together to handle such errors.

Similar to the actions of the memory controller 102 described above, the OS may, for example, retry a previously sent command based on a parity or ECC signal from memory module 106. By default, the OS may be designed and/or configured to handle (e.g., via a trap handler or an error detection and/or correction routine) parity and/or ECC bits. For example, when receiving data, the OS may automatically use the parity/ECC bit(s) to detect an error in transmission of the data and may automatically attempt to correct the data (e.g., in the case of ECC). If the OS may also make various determinations based on the error (or based on repeated errors). For example, the OS may recognize that a particular memory device has completely failed, and may remap or re-encode its data maps to not use the failing device.

According to the present disclosure, the OS (e.g., the trap handler or error detection and/or correction routine) may be altered or modified to behave differently than the default scenario. The OS may handle errors from responder module 126 in a manner similar to that described above for memory controller 102. For example, the OS may automatically retry the command based on the error. The OS may wait an amount of time after receiving the error before retrying the command. The OS may only retry the command a number of times before it “gives up” or stops attempting to retry the command.

In some situations, the communication path from the responder module 126, through the memory bus, through the memory controller and back to the OS may be a long and high-latency path. Thus, such a solution to handling errors initiated by responder module 126 may be used in conjunction with a cache included in the response control module 120 (e.g., inside responder module 126), as described in more detail below. With such a cache, a response (e.g., return data in the case of a read command) may be cached. Thus, an initial command may need to be retried (e.g., routing back to the OS), but subsequent similar commands may not need to be retried if the response data is in the cache.

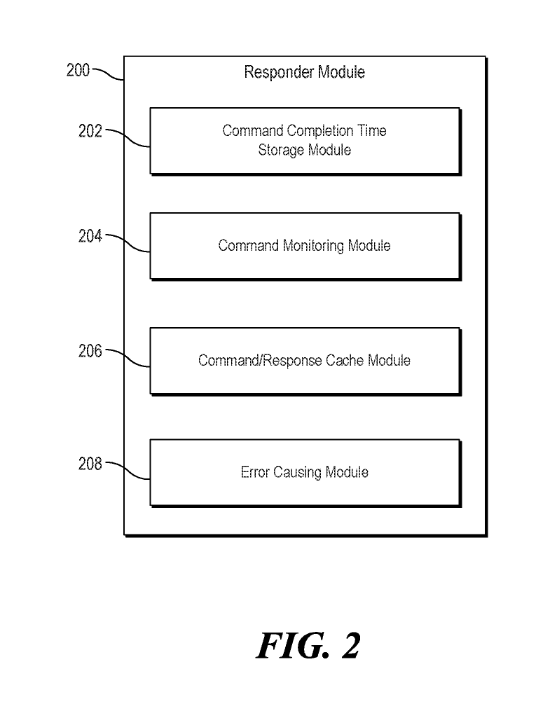

FIG. 2 is a block diagram of an example responder module 200 used to implement response control for memory modules that include or interface with non-compliant memory technologies. Responder module 200 may be similar to responder module 126 of FIG. 1, for example. Responder module 200 may include a number of modules, for example, modules 202, 204, 206, 208. Each of these modules may be electronic circuitry (e.g., hardware and/or firmware) and/or each of these modules may be instructions encoded on a machine-readable storage medium, e.g., that are executable by a microprocessor of the response control module 120. With respect to the modules described and shown herein, it should be understood that part or all of the executable instructions and/or electronic circuitry included within one module may, in alternate embodiments, be included in a different module shown in the figures or in a different module not shown. Each of the modules shown may or may not be present in various examples, and in some examples, additional modules may be present.

Command completion time storage module 202 may determine, receive and/or store an amount of time within which commands are expected to be completed according to a particular data transfer protocol (e.g., DDR). Module 202, for example, may include a ROM or some other programmable storage medium that may store these amounts of time. In the example of a DDR protocol, all commands of a particular type (e.g., reads, writes, etc.), in order to comply with the protocol, must be completed within a particular number of cycles. Module 202 may store these amounts of time (e.g., cycles), and may provide them to various other modules (e.g., 204), for example, such that actual completion times, likely completion times or waiting times may be compared to these stored amounts of time.

Command monitoring module 204 may receive or access commands that enter the memory module, for example, commands that are directed to a non-compliant memory circuit or technology (e.g., 114). Command monitoring module 204 may, in some situations, be referred to as a command monitoring circuit. In some situations, module 204 may only receive or access certain types of commands, for example, only read commands. Command monitoring module 204 may monitor these commands, including the sending of the commands to a non-compliant memory circuit or technology, for example. Command monitoring module 204 may track the status of any return data that such non-compliant memory circuits may return in response to these commands, and how much time has passed since each command was sent to the memory module. Module 204 may compare, for each monitored command, the amount of passed time since the command was sent to expected completion times (e.g., from module 202). If, for example, module 204 determines that return data related to a read command has not been provided by the memory circuit or technology within the expected amount of time, module 204 may communicate with module 208 to initiate an error (e.g., a parity/ECC error as described above).

Command/response cache module 206 may keep track of commands that have been received or accessed by module 204, and may keep track of any return data that has returned from memory circuits/technologies in response to these commands. In this respect, if it is determined (e.g., by module 204) that a command (e.g., a read command) has not completed (e.g., return data ready) within an expected amount of time, while the responder module 200 may initiate an error (e.g., via module 208), the memory circuit/technology may continue to handle the command. Eventually, the memory circuit/technology may provide return data related to the command, and such data (e.g., and perhaps surrounding data) may be stored in module 206. Such data may be stored in module 206 for a period of time, and if the command (or a similar command) is retried at some future time, responder module 200 may be able to quickly return the cached return data, for example, with a response time that may comply with a data transfer protocol (e.g., DDR). As a specific example, if a read command is sent a first time, and the return data is not ready when expected, the return data may be cached when it is ready. Then, when the read command is retried, responder module 200 may recognize (e.g., via modules 204 and 206) that this command was previously received or accessed, and may determine that cached data is available.

Error causing module 208 may have access to parity/ECC bits of the interface between the memory module and the memory bus, and may set these bits to indicate various situations, messages or codes. For example, as described above, responder module 200 (e.g., via module 208) may use parity/ECC bits to indicate that a command has not completed (e.g., in the case of reads) or likely will not be completed (e.g., in the case of writes) within an expected amount of time. As another example, error causing module 208 may use parity/ECC bits to indicate when a response (e.g., response data for a read command) is ready for a previously sent command that was unable to compete within an expected time. Error causing module 208 may, in some situations, be referred to as an error causing circuit.

FIG. 3 is a block diagram of example computing system 100 that implements response control for memory modules that include or interface with non-compliant memory technologies. Computing system 100 may be the same computing system 100 depicted in FIG. 1. Whereas FIG. 1 depicted various features that were associated with issuing read commands, FIG. 3 depicts various features that are associated with issuing write commands, particularly, the responder module monitoring a write buffer module 128, and using command (cmd) parity error bit(s) to indicate that a write command will not be or has not been completed as expected according to a particular data transfer protocol (e.g., DDR). It will be seen, by comparing FIGS. 1 and 3, that various modules and/or components are shared between the two figures. However, for ease of description, some modules and/or components may be shown in FIG. 3 and not in FIG. 1, and vice versa. For example, in FIG. 3, computing system 100 may include a write buffer module 128. It should be understood that some example computing systems may include any combination of the modules and/or components shown in either FIGS. 1 and/or 3. Some example computing systems may include all the components shown in either FIGS. 1 and/or 3.

Write buffer module 128 may include at least one write buffer. Write buffer module 128 may receive and store (e.g., in a first-in first-out manner) write commands from decoder module 124. The write buffer in module 128 may have a size or a capacity, which may determine how many write commands the write buffer can hold at once. The write buffer may be “full” when it is storing the same number of write commands as its size/capacity. The term “used capacity” may refer to the number of write commands that are currently being stored in the write buffer. The term “available capacity” may refer to the number of write commands that the write buffer can currently accept before it is full. Write buffer module 128 may send stored write commands to memory circuits/technologies (e.g., 112 and/or 114), for example, via at least one interface module (e.g., 130 and/or 132). For example, interface modules 130 and/or 132 may indicate to write buffer module 128 when it is available to receive another write command. As another example, if a particular interface module (e.g., 130) is DDR compliant, write buffer module 128 may send stored write commands to the interface module as specified by a DDR data transfer standard (e.g., at a predictable, defined and relatively fast rate). In some examples, for compliant memory circuits/technologies, commands may bypass write buffer module 128, as shown in FIG. 2.

Write buffer module 128 may, at various times (e.g., every cycle), communicate its available capacity to responder module 128, as shown in FIG. 2. Alternatively, responder module 128 may detect the available capacity in write buffer module 128. Thus, at various times (e.g., every cycle), responder module 128 may maintain a snapshot of the number of write commands that write buffer module 128 can accept. If the write buffer is full, the write buffer module may return a zero value to response control credit module. As mentioned above, the present disclosure allows non-compliant memory technologies (e.g., 114) to interface with a compliant (e.g., DDR compliant) memory bus and a compliant memory controller. In some scenarios, non-compliant memory circuits/technologies (e.g., 114) may signal (e.g., via interface module 132) to write buffer module when it can accept additional write commands and/or when it cannot accept any more write commands. Write buffer module 128 may then use such a signal to stop sending stored write commands to such non-compliant memory circuits/technologies. In the meantime, write buffer module 128 may still receive incoming write commands (e.g., at a DDR rate). Thus, in certain scenarios, the write buffer in module 128 may begin to fill up (e.g., the available capacity may reduce).

Responder module 126 may receive or detect, at various times (e.g., every cycle), the available capacity of write buffer module 128. If the write buffer module does not have enough available capacity for write commands to complete within an expected amount of time, responder module 126 may signal an error, for example, a command (cmd) parity error. A command parity bit is a bit/wire/line that already exist in the interface between memory module 106 and memory bus 104 and memory controller 102. A command parity bit may be used to signal an error to the memory controller if a parity error is detected with respect to a command that is sent to the memory module. Various DIMMs have a command parity checking and error signaling controller or mechanism by default, and responder module 126 may utilize (e.g., modify) this controller/mechanism to signal write commands that will be unable to complete within an expected amount of time.

Responder module 126 may determine, receive and/or store an amount of time within which commands (e.g., write commands) are expected to be completed according to a particular data transfer protocol (e.g., DDR). Responder module 126 may also determine based on the available capacity of write buffer module 128 how much time it may take (e.g., best case scenario) for various write commands entering the write buffer to complete (e.g., by being written to the memory circuits/technologies). Responder module 126 may compare these best case times to expected completion times, and if the best case time for a command exceeds the expected time, responder module 126 may initiate a command parity error. Alternatively, instead of considering best-case completion times, responder module may monitor the output of write buffer module 128, to detect when a particular write command has actually been sent to the memory circuit/technology. In this case, responder module 126 may determine that the write command in fact has not completed within the expected time. Alternatively, instead of considering best-case completion times or actual completions, responder module may simply use a command parity error to signal when the write buffer is becoming overly full (e.g., a certain number of available entries).

Memory controller 102 may need to be designed and/or configured to interpret and/or act upon command parity error signals from memory module 106 that indicate that a write command was not completed as expected according to the data transfer protocol. However, it should be understood that an interface of the memory controller 102 may still comply with a particular data transfer standard (e.g., DDR). Various memory controllers by default may retry the command when a command parity error is received. In such a scenario, the default memory controller may suffice. Alternatively, the memory controller 102 may be modified, for example, to retry the command in a similar manner to the way command retries are explained above with regard to FIG. 1.

In some situations, responder module 126 may use a command parity error signal as a serial communication link instead of using it to issue an official command parity error. Responder module 126 may send messages, error codes or the like via the command parity error bit, and the memory controller 102 may be designed and/or configured to detect and or decode such messages or error codes.

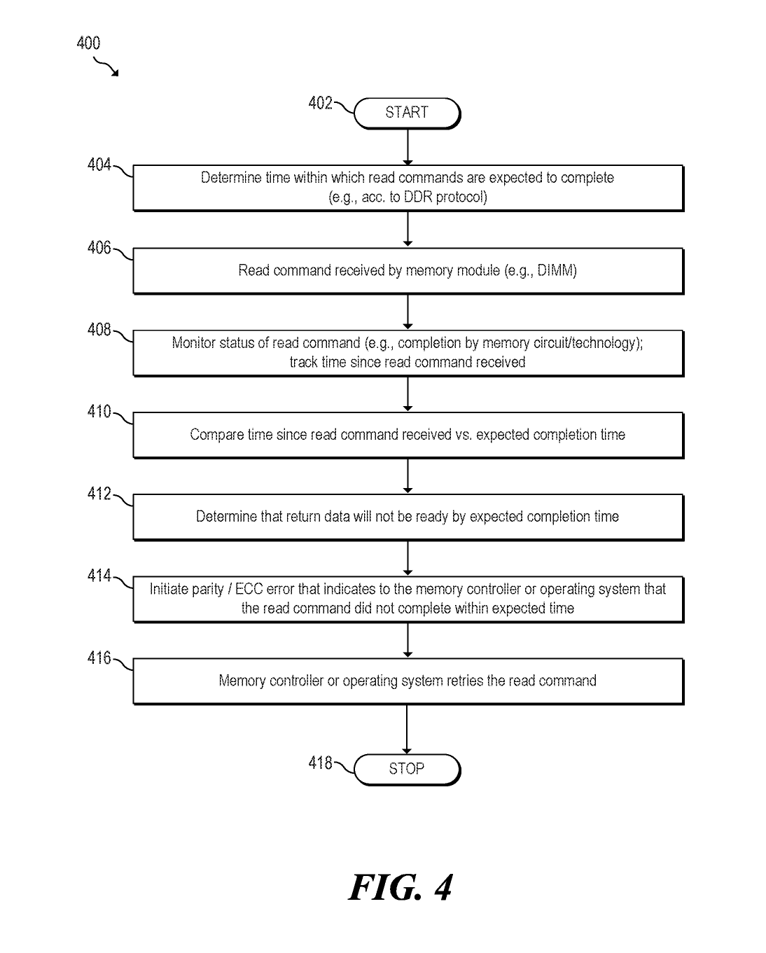

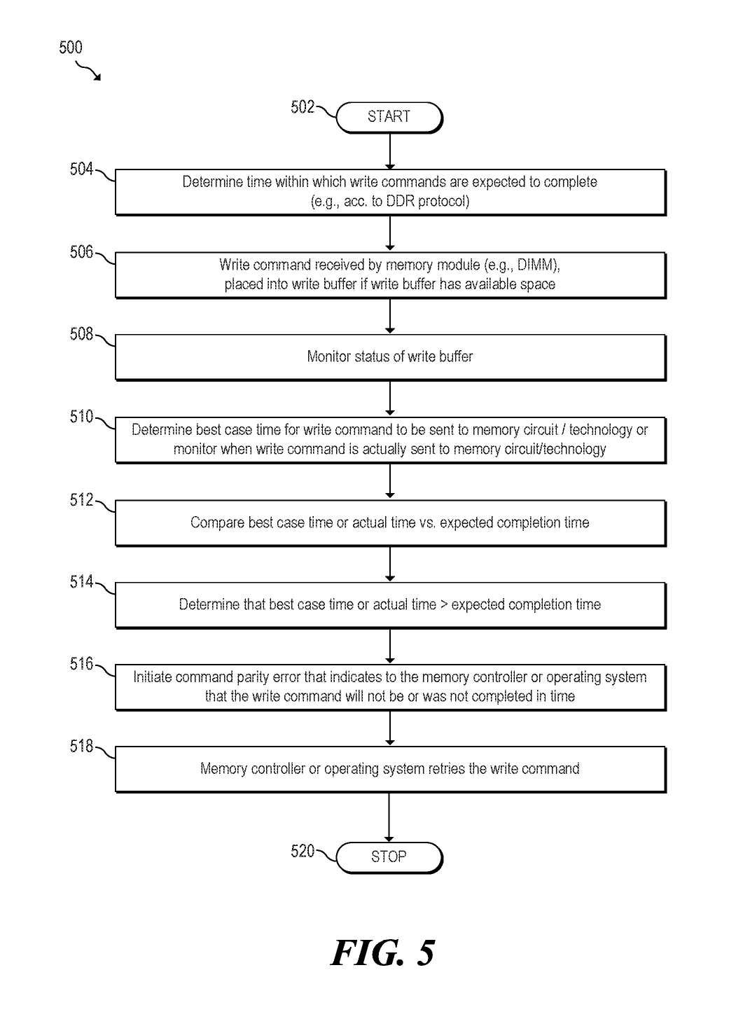

FIG. 4 depicts a flowchart of an example method 400 for response control for memory modules that include or interface with non-compliant memory technologies. FIG. 4 may show various steps by which read commands may be handled, and FIG. 5 may show various steps by which write commands may be handled. Method 400 may be executed by a response control module (e.g., 120 of FIG. 1) or any other suitable electronic circuitry, for example, circuitry on memory module 520 of FIG. 5. Method 400 may be implemented in form of electronic circuitry and/or in the form of executable instructions stored on a machine-readable storage medium, e.g., a machine-readable storage medium disposed in response control module 120. In alternate embodiments of the present disclosure, one or more steps of method 400 may be executed substantially concurrently or in a different order than shown in FIG. 4. In alternate embodiments of the present disclosure, method 400 may include more or less steps than are shown in FIG. 4. In some embodiments, one or more of the steps of method 400 may, at certain times, be ongoing and/or may repeat.

Referring to FIG. 4, method 400 may start at step 402 and continue to step 404, where response control module 120 may determine a time within which read commands are expected to be complete (e.g., according to a DDR protocol). At step 406, a read command may be received by a memory module (e.g., DIMM) on which the response control module 120 is disposed. The read command may be intended to read data from a memory circuit/technology (e.g., a non-compliant memory circuit/technology). At step 408, the response control module 120 may monitor the status of the read command, for example, whether the command has been completed (e.g., return data ready) by the memory circuit/technology. Also at step 408, the response control module 120 may track the time (e.g., cycles) since the read command was received by the memory module. At step 410, the response control module 120 may compare the time since the read command was received to the expected completion time. At step 412, the response control module 120 may determine, based on the time since the command was received, that the return data will not be ready by the expected completion time. At step 414, the response control module 120 may initiate a parity or ECC error that indicates to a memory controller or operating system that the read command did not complete within the expected time. In response to the error, at step 416, the memory controller or operating system may then retry the read command, e.g., after a period of time. Method 400 may eventually continue to step 418, where method 400 may stop.

FIG. 5 depicts a flowchart of an example method 500 for response control for memory modules that include or interface with non-compliant memory technologies. FIG. 5 may show various steps by which write commands may be handled. Method 500 may be executed by a response control module (e.g., 120 of FIG. 3) or any other suitable electronic circuitry, for example, circuitry on memory module 520 of FIG. 5. Method 500 may be implemented in form of electronic circuitry and/or in the form of executable instructions stored on a machine-readable storage medium, e.g., a machine-readable storage medium disposed in response control module 120. In alternate embodiments of the present disclosure, one or more steps of method 500 may be executed substantially concurrently or in a different order than shown in FIG. 5. In alternate embodiments of the present disclosure, method 500 may include more or less steps than are shown in FIG. 5. In some embodiments, one or more of the steps of method 500 may, at certain times, be ongoing and/or may repeat.

Referring to FIG. 5, method 500 may start at step 502 and continue to step 504, where response control module 120 may determine a time within which write commands are expected to be completed (e.g., according to a DDR protocol). At step 506, a write command may be received by a memory module (e.g., DIMM) on which the response control module 120 is disposed. The write command may be intended to write data to a memory circuit/technology (e.g., a non-compliant memory circuit/technology). The write command may be placed into a write buffer of the response control module 120, if the write buffer has available space. At step 508, response control module 120 may monitor the status of the write buffer (e.g., how much available space, where various write commands are in the buffer, etc.). At step 510, response control module 120 may determine a best case time for the write command to be sent to the memory circuit/technology or module 120 may monitor when the write command is actually sent to the memory circuit/technology. At step 512, response control module 120 may compare the best case time or the actual time to the expected completion time. At step 514, response control module 120 may determine that the best case time or the actual time is greater than the expected completion time. At step 516, response control module 120 may initiate a command parity error that indicates to a memory controller or operating system that the write command will not be or was not completed in time. At step 518, the memory controller or operating system, in response to the error, retry the write command. Method 500 may eventually continue to step 520, where method 500 may stop.

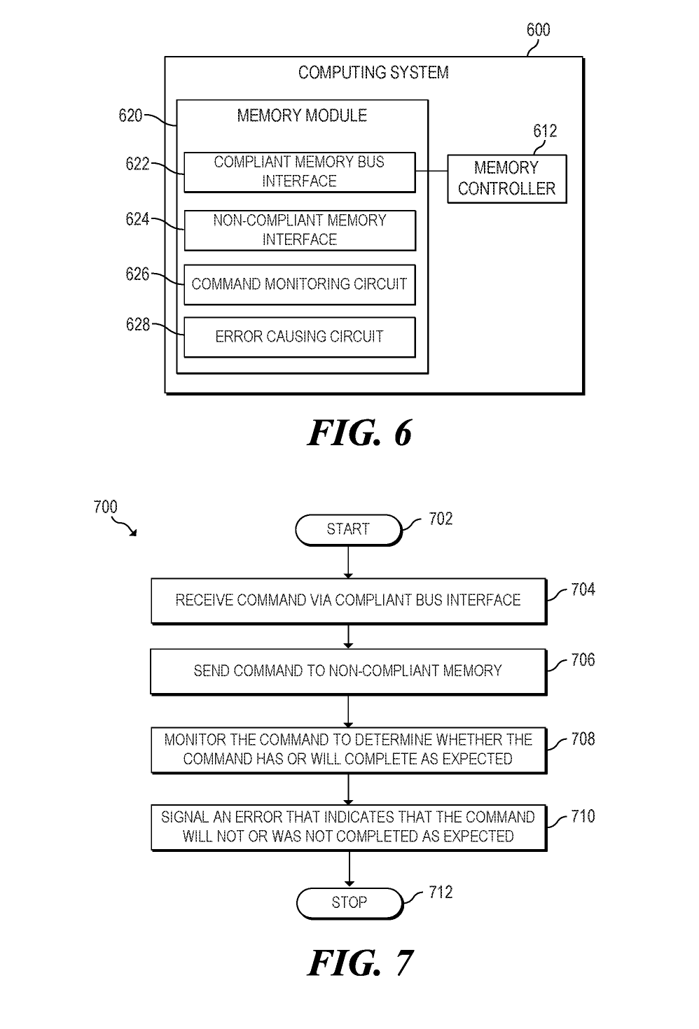

FIG. 6 is a block diagram of an example computing system 600 for response control for memory modules that include or interface with non-compliant memory technologies. Computing system 600 may be any computing system or computing device that includes a memory controller (e.g., 612) that accesses a memory module (e.g., 620), e.g., via a memory bus. More details regarding an example computing system may be described above, for example, with respect to computing system 100 of FIG. 1 and FIG. 3. In the embodiment of FIG. 6, computing system 600 includes a memory controller 612 and a memory module 620. Memory controller 612 may be similar to memory controller 102 of FIGS. 1 and 3, and memory module 620 may be similar to memory module 106, for example.

Memory module 620 may include a number of components 622, 624, 626 and 628. Each of these components may be implemented in form of electronic circuitry and/or in the form of executable instructions stored on a machine-readable storage medium, e.g., a machine-readable storage medium disposed in memory module 620. Such a machine-readable storage medium may be any electronic, magnetic, optical, or other physical storage device that stores executable instructions. Thus, such a machine-readable storage medium may be, for example, Random Access Memory (RAM), an Electrically-Erasable Programmable Read-Only Memory (EEPROM), and the like. In the case of components 622, 624, 626 and 628 being implemented as executable instructions, memory module 620 may include any kind of microprocessor suitable for retrieval and execution of instructions stored in the machine-readable storage medium. Such a processor may fetch, decode, and execute instructions (e.g., components 622, 624, 626, 628) to, among other things, implement response control for memory modules that include or interface with non-compliant memory technologies. With respect to the component boxes (e.g., 622, 624, 626, 628) shown in FIG. 6, it should be understood that part or all of the executable instructions and/or circuitry included within one box may, in alternate embodiments, be included in a different box shown in the figures or in a different box not shown.

Compliant memory bus interface 622 may communicate with memory controller 612 via a memory bus. Interface 622, memory controller 612 and the memory bus may each be compliant with a particular data transfer standard (e.g., DDR). Non-compliant memory interface 624 may interface to a non-compliant memory circuit or technology that does not comply with the data transfer standard. Command monitoring circuit 626 may analyze a command from the memory controller to the non-compliant memory circuit or technology. The command monitoring circuit may determine whether the command has been or will be completed by the non-compliant memory circuit within a defined amount of time. The defined amount of time may be from a set of at least one specified amount of time within which a command should be completed according to the data transfer standard. Error causing circuit 628 may signal to the memory controller or an operating system when the command has not or will not complete within the defined amount of time. The error causing circuit may use a parity bit or error correcting code (ECC) bits of the interface to a memory bus to perform the signaling. The error causing circuit, via setting of the parity bit or ECC bits, may cause the memory controller or the operating system to retry the command after a period of time.

FIG. 7 is a flowchart of an example method 700 for response control for memory modules that include or interface with non-compliant memory technologies. Method 700 may be executed by a memory module (e.g., 620 of FIG. 6) or any other suitable electronic circuitry, for example, response control module 120 of FIGS. 1 and 3. Method 700 may be implemented in form of electronic circuitry and/or in the form of executable instructions stored on a machine-readable storage medium, e.g., a machine-readable storage medium disposed in memory module 620. In alternate embodiments of the present disclosure, one or more steps of method 700 may be executed substantially concurrently or in a different order than shown in FIG. 7. In alternate embodiments of the present disclosure, method 700 may include more or less steps than are shown in FIG. 7. In some embodiments, one or more of the steps of method 700 may, at certain times, be ongoing and/or may repeat.

Method 700 may start at step 702 and continue to step 704, where memory module 620 may receive a command via an interface to a memory bus that complies with a data transfer standard. The memory bus may communicate with a memory controller. At step 706, memory module 620 may send the command to a non-compliant memory circuit or technology that does not comply with the data transfer standard. At step 708, memory module 620 may monitor the command to determine whether the command has been or will be completed by the non-compliant memory circuit within a defined amount of time. At step 710, memory module 620 may signal an error, using a parity bit or error correcting code (ECC) bits, to the memory controller or an operating system when the command has not or will not complete within the defined amount of time. The parity bit or ECC bits are part of the interface to a memory bus that complies with a data transfer standard. Method 700 may eventually continue to step 712, where method 700 may stop.

1. A memory module for response control, the memory module comprising:
an interface to a memory bus that complies with a data transfer standard, wherein the memory bus communicates with a memory controller;
an interface to a non-compliant memory technology that does not comply with the data transfer standard;
a command monitoring circuit to analyze a command from the memory controller to the non-compliant memory technology, wherein the command monitoring circuit determines whether the command has been or will be completed by the non-compliant memory circuit within a defined amount of time within which a command should be completed according to the data transfer standard; and
an error causing circuit that signals to the memory controller or an operating system when the command has not or will not complete within the defined amount of time, wherein the error causing circuit uses a parity bit or error correcting code (ECC) bits of the interface to a memory bus to perform the signaling.

2. The memory module of claim 1, wherein the command is a read command and wherein the command monitoring circuit determines whether the non-compliant memory circuit has return data ready within the defined amount of time.

3. The memory module of claim 1, wherein the command is a write command and wherein the command monitoring circuit determines whether the write command will be or has been sent to the non-compliant memory circuit within the defined amount of time.

4. The memory module of claim 1, wherein the error causing circuit, via setting of the parity bit or ECC bits, causes the memory controller or the operating system to retry the command after a period of time.

5. The memory module of claim 4, further comprising a cache that stores return data for read commands that were not completed within the defined amount of time, such that the memory module can return the return data to the memory controller when the command is retried, wherein the return data can be returned within the defined amount of time after the retried command is received by the memory module.

6. The memory module of claim 1, wherein the data transfer standard is a double data rate (DDR) standard.

7. The memory module of claim 6, wherein the non-compliant memory technology is a non-volatile memory technology.

8. The memory module of claim 1, wherein the signaling to the memory controller or operating system is performed without using additional communication wires beyond what the memory bus uses to communicate with the memory module and the non-compliant memory technology according to the data transfer standard.

9. A method for response control executed in a memory module, the method comprising:
receiving a command via an interface to a memory bus that complies with a data transfer standard, wherein the memory bus communicates with a memory controller;
sending the command to a non-compliant memory technology that does not comply with the data transfer standard;
monitoring the command to determine whether the command has been or will be completed by the non-compliant memory circuit within a defined amount of time within which a command should be completed according to the data transfer standard; and
signaling an error, using a parity bit or error correcting code (ECC) bits, to the memory controller or an operating system when the command has not or will not complete within the defined amount of time, wherein the parity bit or ECC bits are part of the interface to a memory bus that complies with a data transfer standard.

10. The method of claim 9, wherein the parity bit or ECC bits are encoded in a manner such that the memory controller or operating system can distinguish between a real parity or ECC error and an error that indicates that a command has not or will not complete within the defined amount of time.

11. The method of claim 9, wherein the signaling causes the memory controller or the operating system to retry the command after a period of time.

12. The method of claim 11, wherein signaling the error further includes encoding the ECC bits or data bits of the interface to the memory bus with at least one of the following pieces of information:
an indication that distinguishes the error from a real parity or ECC error;
an amount of time that the memory controller or operating system should wait before retrying the command; and
a number of times that the memory controller or operating system should retry the command before giving up.

13. A computing system, comprising:
a memory bus coupled to a memory controller, wherein the memory bus and memory controller comply with a double data rate (DDR) data transfer standard;
a memory module that includes or interfaces with a non-compliant memory technology that does not comply with the DDR data transfer standard; and
a response control circuit that is on or connected to the memory module, the response control circuit including:
an interface to the memory bus, and an interface to the non-compliant memory technology;
a command monitoring circuit to analyze a read command from the memory controller to the non-compliant memory technology, wherein the command monitoring circuit determines whether return data for the read command is ready at the non-compliant memory technology within a defined amount of time within which read commands should be completed according to the data transfer standard; and
an error causing circuit that signals to the memory controller or an operating system of the computing system when the return data is not ready within the defined amount of time, wherein the error causing circuit uses a parity bit or error correcting code (ECC) bits of the interface to a memory bus to perform the signaling.

14. The computing system of claim 13, wherein the error causing circuit, via setting of the parity bit or ECC bits, causes the memory controller or the operating system to retry the read command after a period of time.

15. The computing system of claim 13, wherein the data transfer standard is a double data rate (DDR) standard, and wherein the non-compliant memory technology is a non-volatile memory technology.
